(19) United States
(12) Patent Application Publication
(10) Pub. No.: US 2014/0264952 A1
(43) Pub. Date: Sep. 18, 2014

(54) SUPPLEMENTING WIRE BONDS

(71) Applicant: POWER INTEGRATIONS, INC., San Jose, CA (US)

(72) Inventor: Jayson M. DENNING, Redwood City, CA (US)

(73) Assignee: POWER INTEGRATIONS, INC., San Jose, CA (US)

(21) Appl. No.: 13/797,324

(22) Filed: Mar. 12, 2013

(51) Int. Cl. H01L 23/49

(52) U.S. Cl. CPC H01L 23/49
USPC 257/784

(57) ABSTRACT

Systems and techniques for supplementing wire bonds. In one embodiment, a device includes a body having a first surface, a first wire bond pad disposed on the first surface, a first wire that is wire bonded to the first wire bond pad to form a contact between the first wire and the first wire bond pad, a first supplemental conductor disposed to form a supplemental conduit between the first wire and the first wire bond pad, a second wire bond pad disposed on the first surface, a second wire that is wire bonded to the second wire bond pad to form a contact between the second wire and the second wire bond pad, and a second supplemental conductor disposed to form a supplemental conduit between the second wire and the second wire bond pad. The first supplemental conductor is discrete from the second supplemental conductor.

### BACKGROUND

1. Field

This disclosure relates to supplementing wire bonds.

2. Description of Related Art

Wire bonding is commonly used to form electrical conduits to semiconductor dies, printed circuit boards, and other components. In wire bonding, a metallic wire can be mechanically joined to a site by bringing the wire into contact with a site while inputting sufficient energy to join the wire to the site. The input energy can include heat (e.g., to nearly melt or melt the tip of the wire that contacts the site), ultrasound, compressive force, and/or combinations of these and other types of energy. With metallic wires and sites, the input energy can cause interdiffusion of the metals from the wire and site and form a bond that has sufficient mechanical integrity to withstand subsequent handling (e.g., during packaging) while providing an electrical conduit to the site.

The wires used in wire bonding can be made from any of a variety of different metals. Although gold wires are traditional, wire bond wires can be made from, e.g., aluminum, copper, silver, platinum, and alloys and combinations of these and other conductive metals. The sites to which the wires are bonded can be formed of any of a variety of different electrical conductors, including gold, aluminum, and other conductive metals.

### DESCRIPTION OF THE FIGURES

Non-limiting and non-exhaustive embodiments are described with reference to the following figures, wherein like reference numerals refer to like parts throughout the various views unless otherwise specified.

FIGS. 1 and 2 are schematic cross-sectional views of wire bond connections between sites and wires.

FIGS. 3, 4, and 6 are schematic cross-sectional views of wire bond connections between sites and wires.

FIG. 5 is a schematic cross-sectional view of a collection of wire bond connections between a site and two or more wires.

FIG. 7 is a schematic representation of a power component.

### DETAILED DESCRIPTION

In the following description, numerous specific details are set forth in order to provide a thorough understanding. It will be apparent, however, to one having ordinary skill in the art that the specific detail need not be employed.

FIG. 1 is a schematic cross-sectional view of a wire bond connection 100 between a site 105 and a wire 110. In the illustrated implementation, site 105 is a bond pad or contact pad that is itself joined to a semiconductor die or other substrate 115 at an interface 120. Connection 100 allows wire 110 to conduct, e.g., electrical signals and/or power between an unillustrated location and a component that is electrically coupled to site 105.

In the illustrated example, connection 100 is a “ball bond” connection in that wire 110 includes a generally bulbous terminus 125 that connects to site 105. The particular shape of terminus 125 generally depends on the shape of the wire bonding tool used to form connection 100, the properties of wire 110, and other parameters. Other shapes are thus possible. Also, other wire bond connections (such as connection 200 in FIG. 2) can be shaped like wedges and are referred to as “wedge bonds.”

Regardless of the particular shape of terminus 125, a contact interface 130 is formed between wire 110 and site 105. Contact interface 130 can include various features characteristic of the wire bonding process used to form wire bond connection 100 and the resultant wire bonds. For example, in some instances, contact interface 130 can include voids or gaps between wire 110 and site 105. Such voids and gaps can arise during the wire bonding process itself or subsequently, e.g., during annealing or other heating, including heating associated with the conduction of current through wire bond connection 100. In some cases, such voids and gaps can impair the electrical and/or thermal conductivity of the conduit between wire 110 and site 105 provided by contact interface 130.

As another example, in some instances, contact interface 130 can include compositions characteristic of wire bonding and wire bonds. For example, when site 105 and wire 110 are made from different conductive metals, contact interface 130 can include intermetallic compounds. Such intermetallic compounds can be formed during the wire bonding process itself or subsequently, e.g., during annealing or other heating, including heating associated with the conduction of current through wire bond connection 100. Some such intermetallic compounds are less electrically and/or thermally conductive than the conductive metals forming site 105 and wire 110 and may in some cases also impair electrical and/or thermal conductivity of the conduit between wire 110 and site 105 provided by contact interface 130. As yet another example, in some instances, contact interface 130 can include contaminants such as metallic oxides and organic and other process residue. Some such contaminants are less electrically and/or thermally conductive than the conductive metals forming site 105 and wire 110 and may in some cases impair the electrical and/or thermal conductivity of the conduit between wire 110 and site 105 provided by contact interface 130.

FIG. 2 is a schematic cross-sectional view of a wire bond connection 200 between a site 205 and a wire 210. In the illustrated implementation, site 205 is a bond pad or contact pad that is itself joined to a semiconductor circuit die or other substrate 215 at an interface 220. Connection 200 allows wire 210 to conduct, e.g., electrical signals and/or power between an unillustrated location and a component that is electrically coupled to site 205.

In the illustrated example, connection 200 is a “wedge bond” connection in that wire 205 includes a generally wedge-shaped region 225 that connects to site 205. The particular shape of region 225 generally depends on the shape of the wire bonding tool used to form connection 200, the properties of wire 210, and other parameters. Other shapes are thus possible.

Regardless of the particular shape of region 225, a contact interface 230 is formed between wire 210 and site 205. Contact interface 230 can include various features characteristic of the wire bonding process used to form wire bond connection 200 and the resultant wire bonds, including those described above with respect to connection 100 (FIG. 1). The electrical and/or thermal conductivity between wire 210 and site 205 provided by contact interface 230 may in some cases be impaired by those features.

FIG. 3 is a schematic cross-sectional view of a wire bond connection 300 between a site 305 and a wire 310. Wire 310 and site 305 may include a conductive material, including any of a variety of different metals, such as gold, aluminum, copper, silver, platinum, and alloys and combinations of these and other conductive metals.

In the illustrated implementation, site 305 is a bond pad or contact pad that is itself joined to a semiconductor circuit die or other substrate 315 at an interface 320. A contact interface 330 is formed between wire 310 and site 305. Contact interface 330 may include various features characteristic of the wire bonding process and wire bonds, including those described above with respect to connection 100 (FIG. 1).

In addition to contact interface 330, wire bond connection 300 also includes a supplemental conductor 335. Supplemental conductor 335 is in general an electrically conductive solid that contacts site 305 at a site/supplemental conductor interface 340 and contacts wire 310 at a wire/supplemental conductor interface 345 to provide an electrical and/or thermal conduit between wire 310 and site 305 that supplements the electrical and/or thermal conduit provided by contact interface 330. Supplemental conductor 335 can in general provide metallic electrical conduction at room temperature.

Supplemental conductor 335 can be formed of any of a number of different electrically conductive solids. For example, in some implementations, supplemental conductor 335 can be formed of a conductive adhesive (e.g., a conductive epoxy adhesive) that is dispensed in a liquid state onto wire bond connection 300 after wire 310 is wire bonded to site 305 and later hardens. As another example, supplemental conductor 335 can be formed of a conductive solder. The solder can be, e.g., introduced in a liquid, solid, or paste state onto wire bond connection 300 after wire 310 is wire bonded to site 305.

In the illustrated implementation, supplemental conductor 335 contacts and forms interfaces 340, 345 with a single wire 310 and with a single site 305 that are wire bonded. As discussed further below, supplemental conductors in other implementations can at times form interfaces with multiple wires (see, e.g., FIG. 5). However, even when a supplemental conductor is disposed to form wire/supplemental conductor interfaces with multiple wires, each of those wires is wire bonded to a single site. Such supplemental conductors thus provide supplemental electrical and thermal conduction exclusively between a wire and a site that are wire bonded.

In the illustrated cross-section, site/supplemental conductor interface 340 extends between a first boundary 370 (shown to the left of contact interface 330) and a second boundary 375 (shown to the right of contact interface 330). Boundaries 370, 375 are both within outer edges 380 of the top surface of site 305. In some implementations, supplemental conductor 335 forms site/supplemental conductor interface 340 circumferentially around the entire contact interface 330. However, this is not necessarily the case and site/supplemental conductor interface 340 can be formed, e.g., only on one side of contact interface 330.

In the illustrated implementation, supplemental conductor 335 forms wire/supplemental conductor interface 345 circumferentially around the entirety of terminus 325 of wire 310, as well as circumferentially around a portion of wire 310 above a neck 350 of terminus 325. However, this is not necessarily the case. For example, in some implementations, supplemental conductor 335 need not contact wire 310 above neck 350 but rather can form wire/supplemental conductor interface 345 only with a sidewall 355 of terminus 325. As another example, in some implementations, supplemental conductor 335 can form wire/supplemental conductor interface 345 only with a portion of sidewall 355. However, in general, contact between supplemental conductor 335 and wire 310 above neck 350 can provide additional mechanical integrity to wire bond connection 300 by reducing the risk of mechanical failure at neck 350.

In the illustrated implementation, wire/supplemental conductor interface 345 is shown as conforming with wire 310 and site/supplemental conductor interface 310 is shown as conforming with site 305. This is not necessarily the case. Indeed it may be likely in some implementations that an air or other gap is found, e.g., at a circumferential junction 360 between terminus 325 and site 305.

In some implementations, the electrical conduit between wire 310 and site 305 provided by supplemental conductor 335 can improve the lifespan and reduce the failure rate of a component that includes wire bond connection 300 relative to a component that includes a wire bond connection 100 that has the same chemical and mechanical properties but lacks supplemental conductor 335. For example, the electrical and thermal conductivity between wire 310 and site 305 can be impaired by various features characteristic of the wire bonding process and wire bonds. Although these characteristic features may be present in contact interface 330, the electrical and thermal conduit between wire 310 and site 305 provided by supplemental conductor 335 can reduce the likelihood that the impairment due to these characteristic features leads to failure.

There are a variety of different physical mechanisms by which supplemental conductor 335 can reduce the likelihood of failure. In addition to mechanical reinforcement of wire bond connection 300—and in some cases neck 350—the electrical conduit provided by supplemental conductor 335 is effectively in parallel with the electrical conduit provided by contact interface 330. Current between wire 310 and site 305 will thus flow through both supplemental conductor 335 and contact interface 330. Such parallel current flow reduces the impact of any impairment of the electrical conductivity between wire 310 and site 305 by features characteristic of the wire bonding process and wire bonds.

As another example, a substrate 315 that includes a wire bond connection 300 with supplemental conductor 335 may have a larger effective heat capacity than a device that includes a wire bond connection without supplemental conductor 335. In particular, such a substrate 315 may be able to disperse heat and otherwise resist temperature changes better. The relatively larger effective heat capacity can be provided not only by the intrinsic heat capacity of supplemental conductor 335 itself, but also by virtue of supplemental conductor 335 providing a supplemental thermal conduit between site 305 and wire 310 that is in parallel with the thermal conduit provided by contact interface 330. With features characteristic of wire bonding and wire bonds in some instances impairing the thermal conductivity of contact interface 330, the thermal conduit provided by supplemental conductor 335 may allow heat to flow more easily between wire 310 and site 305 and away from substrate 315.

The increased effective heat capacity provided by supplemental conductor 335 is particularly relevant in the context of substrates 315 that include power components such as power diodes, high-voltage field effect transistors, insulated gate bipolar transistors, electrical components made from wide bandgap materials, and the like. In particular, the currents conducted to and from power components are often quite large. For example, power diodes may be rated to conduct average currents in excess of an ampere (e.g., three amperes or more) and included in a package designed for attachment to a heat sink. At times, diode and other power component currents may transiently surge. Further, such currents may flow through relatively high electrical impedance elements such as PN junctions in the vicinity of site 305. Relatively high current flows through relatively high electrical impedance elements leads to increased heating that can change the behavior of or even damage power components. Further, even if the power components themselves are not impacted, the heating can damage the interface (e.g., interfaces 120, 320) between a site and a substrate (e.g., substrates 115, 315) leading to reduced power component lifetimes. However, supplemental conductor 335 can improve the dispersal of the heat and reduce the temperature change of the power component for a given set of operational conditions.

FIG. 4 is a schematic cross-sectional view of a wire bond 400 between a site 405 and a wire 410. Wire 410 and site 405 may include a conductive material, including any of a variety of different metals, such as gold, aluminum, copper, silver, platinum, and alloys and combinations of these and other conductive metals.

In the illustrated implementation, site 405 is a bond pad or contact pad that is itself joined to a semiconductor circuit die or other substrate 415 at an interface 420. A contact interface 430 is formed between site 405 and wire 410. Contact interface 430 may include various features characteristic of the wire bonding process and wire bonds, including those described above with respect to connection 100 (FIG. 1).

In addition to contact interface 430, wire bond connection 400 also includes a supplemental conductor 435. Supplemental conductor 435 is in general an electrically conductive solid that contacts site 405 at a site/supplemental conductor interface 440 and contacts wire 410 at a wire/supplemental conductor interface 445 to provide an electrical and thermal conduit between wire 410 and site 405 that supplements the electrical and thermal conduit provided by contact interface 430. For example, in some implementations, supplemental conductor 435 can be formed of a conductive adhesive (e.g., a conductive epoxy adhesive) that is dispensed in a liquid state onto wire bond connection 400 after wire 410 is wire bonded to site 405 and later hardens. As another example, supplemental conductor 435 can be formed of a conductive solder. The solder can be, e.g., introduced in a liquid, solid, or paste state onto wire bond connection 400 after wire 410 is wire bonded to site 405.

In the illustrated implementation, supplemental conductor 435 is configured so that site/supplemental conductor interface 440 extends across the entirety of a top surface 465 of site 405. In particular, site/supplemental conductor interface 440 extends between a first boundary 470 (shown to the left of contact interface 430) and a second boundary 475 (shown to the right of contact interface 430) along edges 480 of the top surface of site 405. With site/supplemental conductor interface 440 being relatively larger, the thermal conductivity between site 405 and supplemental conductor 435 is increased and supplemental conductor 435 can improve the dispersal of the heat from substrate 415.

Moreover, a substrate 415 that includes a wire bond connection 400 with supplemental conductor 435 may have a larger effective heat capacity than a device that includes a wire bond connection without supplemental conductor 435. In particular, the relatively larger effective heat capacity can also be increased not only by the intrinsic heat capacity of supplemental conductor 435 itself, but also by virtue of supplemental conductor 435 providing a supplemental thermal conduit between site 405 and wire 410 that is in parallel with the thermal conduit provided by contact interface 430. With features characteristic of wire bonding and wire bonds in some instances impairing the thermal conductivity of contact interface 430, the thermal conduit provided by supplemental conductor 435 may allow heat to flow more easily between wire 410 and site 405 and away from substrate 415.

The increased effective heat capacity provided by supplemental conductor 435 is particularly relevant in the context of substrates 415 that include power components such as power diodes, high-voltage field effect transistors, insulated gate bipolar transistors, electrical components made from wide bandgap materials, and the like. In particular, the currents conducted to and from power components are often quite large. For example, power diodes may be rated to conduct average currents in excess of an ampere (e.g., three amperes or more) and included in a package designed for attachment to a heat sink. At times, diode and other power component currents may transiently surge. Further, such currents may flow through relatively high electrical impedance elements such as PN junctions in the vicinity of site 405. Relatively high current flows through relatively high electrical impedance elements leads to increased heating that can change the behavior of or even damage power components. Further, even if the power components themselves are not impacted, the heating can damage the interface (e.g., interfaces 120, 420) between a site and a substrate (e.g., substrates 115, 415) leading to reduced power component lifetimes. However, supplemental conductor 435 can improve the dispersal of the heat and reduce the temperature change of the power component for a given set of operational conditions.

Additionally, similar to supplemental conductor 335, supplemental conductor 435 may provide mechanical reinforcement of wire bond connection 400—and in some cases neck 450—as well as provide an electrical conduit that is effectively in parallel with the electrical conduit provided by contact interface 430. Current between wire 410 and site 405 will thus flow through both supplemental conductor 435 and contact interface 430. Such parallel current flow reduces the impact of any impairment of the electrical conductivity between wire 410 and site 405 by features characteristic of the wire bonding process and wire bonds.

FIG. 5 is a schematic cross-sectional view of a collection 500 of wire bond connections between a site 505 and two or more wires 510. Wires 510 and site 505 may include a conductive material, including any of a variety of different metals, such as gold, aluminum, copper, silver, platinum, and alloys and combinations of these and other conductive metals.

In the illustrated implementation, site 505 is a bond pad or contact pad that is itself joined to a semiconductor circuit die or other substrate 515 at an interface 520. Each contact interface 530 is formed between a respective one of wires 510 and site 505. Each contact interface 530 may include various features characteristic of the wire bonding process and wire bonds, including those described above with respect to connection 100 (FIG. 1).

In addition to contact interfaces 530, collection 500 also includes a supplemental conductor 535. Supplemental conductor 535 is in general an electrically conductive solid that contacts site 505 at a site/supplemental conductor interface 540 and contacts wires 510 at wire/supplemental conductor interfaces 545 to provide an electrical and thermal conduit between wires 510 and site 505 that supplements the electrical and thermal conduits provided by contact interfaces 530. For example, in some implementations, supplemental conductor 535 can be formed of a conductive adhesive (e.g., a conductive epoxy adhesive) that is dispensed in a liquid state onto wire bond connection 500 after each individual wire 510 is wire bonded to site 505 or after two or more wires 510 are wire bonded to site 505 and later hardens. As another example, supplemental conductor 535 can be formed of a conductive solder. The solder can be, e.g., introduced in a liquid, solid, or paste state onto wire bond connection 500 after each individual wire 510 is wire bonded to site 505 or after two or more wires 510 are wire bonded to site 505.

There are a variety of different physical mechanisms by which supplemental conductor 535 can reduce the likelihood of failure. In addition to mechanical reinforcement of wire bond connection 500, the electrical conduit provided by supplemental conductor 535 is effectively in parallel with the electrical conduit provided by contact interfaces 530. Current between wires 510 and site 505 will thus flow through both supplemental conductor 535 and contact interface 530. Such parallel current flow reduces the impact of any impairment of the electrical conductivity between wires 510 and site 505 by features characteristic of the wire bonding process and wire bonds.

As another example, a substrate 515 that includes a wire bond connection 500 with supplemental conductor 535 may have a larger effective heat capacity than a device that includes a wire bond connection without supplemental conductor 535. In particular, such a substrate 515 may be able to disperse heat and otherwise resist temperature changes better. The relatively larger effective heat capacity can be provided not only by the intrinsic heat capacity of supplemental conductor 535 itself, but also by virtue of supplemental conductor 535 providing a thermal conduit between site 505 and wires 510 that is in parallel with the thermal conduit provided by contact interfaces 530. With features characteristic of wire bonding and wire bonds in some instances impairing the thermal conductivity of contact interfaces 530, the thermal conduit provided by supplemental conductor 535 may allow heat to flow more easily between wires 510 and site 505 and away from substrate 515.

The increased effective heat capacity provided by supplemental conductor 535 is particularly relevant in the context of substrates 515 that include power components such as power diodes, high-voltage field effect transistors, insulated gate bipolar transistors, electrical components made from wide bandgap materials, and the like. In particular, the currents conducted to and from power components are often quite large. At times, those currents may transiently surge. Further, power components can include relatively high electrical impedance elements such as PN junctions in the vicinity of site 505. Relatively high current flows through relatively high electrical impedance elements leads to increased heating that can change or even damage the behavior of power components. Further, even if the power components themselves are not impacted, the heating can damage the interface (e.g., interfaces 120, 520) between a site and a substrate (e.g., substrates 115, 515) leading to reduced power component lifetimes. However, supplemental conductor 535 can improve the dispersal of the heat and reduce the temperature change of the power component for a given set of operational conditions.

FIG. 6 is a schematic cross-sectional view of a wire bond connection 600 between a site 605 and a wire 610. Wire 610 and site 605 may include a conductive material, including any of a variety of different metals, such as gold, aluminum, copper, silver, platinum, and alloys and combinations of these and other conductive metals.

In the illustrated implementation, site 605 is a bond pad or contact pad that is itself joined to a semiconductor circuit die or other substrate 615 at an interface 620. A contact interface 630 is formed between site 605 and a bulbous terminus 625 of wire 610. Contact interface 630 may include various features characteristic of the wire bonding process and wire bonds, including those described above with respect to connection 100 (FIG. 1).

In addition to contact interface 630, wire bond connection 600 also includes a supplemental conductor 635. Supplemental conductor 635 is in general an electrically conductive solid that contacts site 605 at a site/supplemental conductor interface 640 and contacts wire 610 at a wire/supplemental conductor interface 645 to provide an electrical and thermal conduit between wire 610 and site 605 that supplements the electrical and thermal conduit provided by contact interface 630.

Supplemental conductor 635 can be formed of any of a number of different electrically conductive solids. For example, in some implementations, supplemental conductor 635 can be formed of a conductive adhesive (e.g., a conductive epoxy adhesive) that is dispensed in a liquid state onto wire bond connection 600 after wire 610 is wire bonded to site 605 and later hardens. As another example, supplemental conductor 635 can be formed of a conductive solder. The solder can be, e.g., introduced in a liquid, solid, or paste state onto wire bond connection 600 after wire 610 is wire bonded to site 605.

In the illustrated implementation, supplemental conductor 635 exclusively contacts and forms interfaces 640, 645 with a single wire 610 and with a single site 605 that are wire bonded.

In the illustrated cross-section, site/supplemental conductor interface 640 extends to a first boundary 670 (shown to the left of contact interface 630). Boundary 670 is within outer edges 680 of the top surface of site 605. In some implementations, supplemental conductor 635 forms site/supplemental conductor interface 640 only on one side of wire 610. However, this is not necessarily the case and site/supplemental conductor interface 640 can be formed, e.g., circumferentially around wire 610.

In the illustrated implementation, supplemental conductor 635 forms wire/supplemental conductor interface 645 only on a portion of wire 610. However, this is not necessarily the case. For example, in some implementations, supplemental conductor 635 can contact the entire circumference of wire 310.

In the illustrated implementation, wire/supplemental conductor interface 645 is shown as conforming with wire 610 and site/supplemental conductor interface 640 is shown as conforming with site 605. This is not necessarily the case. Indeed it may be likely in some implementations that an air or other gap is found, e.g., at a position 660 between wire 610 and site 605.

In some implementations, the electrical conduit between wire 610 and site 605 provided by supplemental conductor 635 can improve the lifespan and reduce the failure rate of a component that includes wire bond connection 600 relative to a component that includes a wire bond connection 200 that has the same chemical and mechanical properties but lacks supplemental conductor 635. For example, the electrical and thermal conductivity between wire 610 and site 605 can be impaired by various features characteristic of the wire bonding process and wire bonds. Although these characteristic features may be present in contact interface 630, the electrical and thermal conduit between wire 610 and site 605 provided by supplemental conductor 635 can reduce the likelihood that the impairment due to these characteristic features leads to failure.

In some implementations of wire bond connection 600, the volume, composition, and handling of supplemental conductor 635 can be configured so that site/supplemental conductor interface 640 extends across the entirety of a top surface 665 of site 605. In some instances, a collection of wire bond connections 600 can be formed between a site 605 and two or more wires 610. However, even when a supplemental conductor is disposed to form wire/supplemental conductor interfaces with multiple wires, each of those wires is wire bonded to a single site and such supplemental conductors provide supplemental electrical and/or thermal conduction exclusively between a wire and a site that are wire bonded.

There are a variety of different physical mechanisms by which supplemental conductor 635 can reduce the likelihood of failure. In addition to mechanical reinforcement of wire bond connection 600, the electrical conduit provided by supplemental conductor 635 is effectively in parallel with the electrical conduit provided by contact interface 630. Current between wire 610 and site 605 will thus flow through both supplemental conductor 635 and contact interface 630. Such parallel current flow reduces the impact of any impairment of the electrical conductivity between wire 610 and site 605 by features characteristic of the wire bonding process and wire bonds.

As another example, a substrate 615 that includes a wire bond connection 600 with supplemental conductor 635 may have a larger effective heat capacity than a device that includes a wire bond connection without supplemental conductor 635. In particular, such a substrate 615 may be able to disperse heat and otherwise resist temperature changes better. The relatively larger effective heat capacity can be provided not only by the intrinsic heat capacity of supplemental conductor 635 itself, but also by virtue of supplemental conductor 635 providing a thermal conduit between site 605 and wire 610 that is in parallel with the thermal conduit provided by contact interface 630. With features characteristic of wire bonding and wire bonds in some instances impairing the thermal conductivity of contact interface 630, the thermal conduit provided by supplemental conductor 635 may allow heat to flow more easily between wire 610 and site 605 and away from substrate 615.

The increased effective heat capacity provided by supplemental conductor 635 is particularly relevant in the context of substrates 615 that include power components such as power diodes, high-voltage field effect transistors, insulated gate bipolar transistors, electrical components made from wide bandgap materials, and the like. In particular, the currents conducted to and from power components are often quite large. At times, those currents may transiently surge. Further, power components can include relatively high electrical impedance elements such as PN junctions in the vicinity of site 605. Relatively high current flows through relatively high electrical impedance elements leads to increased heating that can change or even damage the behavior of power components. Further, even if the power components themselves are not impacted, the heating can damage the interface (e.g., interfaces 220, 620) between a site and a substrate (e.g., substrates 215, 615) leading to reduced power component lifetimes. However, supplemental conductor 635 can improve the dispersal of the heat and reduce the temperature change of the power component for a given set of operational conditions.

FIG. 7 is a schematic representation of a high-voltage power component 700. Power component 700 includes a body 705 and contacts 710, 715, 720 disposed on surfaces 725, 730 of body 705. Body 705 can be a semiconductor die with a high-voltage power transistor formed therein. Contacts 710, 715, 720 may include a conductive material, including any of a variety of different metals, such as gold, aluminum, copper, silver, platinum, and alloys and combinations of these and other conductive metals. Contacts 710, 715, 720 can be, e.g., respective of gate, source, and drain contacts of a field effect transistor or respective of emitter, base, and collector contacts of a bipolar transistor. In a high-voltage power transistor, voltages in excess of 30 volts or more can be supported between a source and drain. Further, the current flow path between the source and drain can include a PN junction. Charge carriers flowing across the junction can result in heating of high voltage power component 700.

Although contacts 715, 720 are each shown on respective opposite surfaces 725, 730 of power component 700 (as is typically consistent with a vertical power transistor), this is not necessarily the case and contacts 715, 720 can be on a single surface of power component 700.

One or more of contacts 710, 715, 720 of power component 700 can include one or more wire bond connections. For example, one or more of contacts 710, 715, 720 of power component 700 can include one or more of wire bond connections 300 (FIG. 3), 400 (FIG. 4), 500 (FIG. 5), and/or 600 (FIG. 6). If two or more contacts of 710, 715, 720 include supplemental conductors, the respective supplemental conductors of each contact are discrete from one another and constitute individual entities. In some implementations, boundaries of the interfaces between the supplemental conductors and the contacts can be within the outer edges of a top surface of the contacts.

In such a power component 700, an electrical conduit between bonding wires and one or more of contacts 710, 715, 720 provided by supplemental conductors can improve the lifespan and reduce the failure rate of power component 700 relative to a power component 700 that lacks a supplemental conductor. In particular, a supplemental conductor can improve the dispersal of the heat and reduce the temperature change of power component 700 for a given set of operational conditions.

In some implementations, high-voltage power component 700 can be included in a battery charger (e.g., for a smart phone or other portable electronic device) or a power converter for LED lights.

The above description of illustrative examples is not intended to be exhaustive. Although specific implementations of, and examples for, are described herein for illustrative purposes, various equivalent modifications are possible without departing from the broader spirit and scope. Indeed, it is appreciated that the specific example voltages, currents, frequencies, power range values, times, etc., are provided for explanation purposes and that other values may also be employed in other embodiments and examples in accordance with these teachings.

These modifications can be made to examples in light of the above detailed description. For example, in some implementations, a supplemental conductor can be formed of a thermally conductive but electrically isolating material. In such cases, the supplemental conductor would provide a thermal conduit but not an electrical conduit. The terms used in the following claims should not be construed to limit the invention to the specific embodiments disclosed in the specification and the claims. The present specification and figures are accordingly to be regarded as illustrative rather than restrictive.

1. A device comprising:
a body having a first surface;
a first wire bond pad disposed on the first surface;
a first wire that is wire bonded to the first wire bond pad to form a contact between the first wire and the first wire bond pad;
a first supplemental conductor disposed to form a supplemental conduit between the first wire and the first wire bond pad;
a second wire bond pad disposed on the first surface;
a second wire that is wire bonded to the second wire bond pad to form a contact between the second wire and the second wire bond pad; and
a second supplemental conductor disposed to form a supplemental conduit between the second wire and the second wire bond pad, wherein the first supplemental conductor is discrete from the second supplemental conductor.

2. The device of claim 1, wherein:
a boundary of an interface between the first supplemental conductor and the first wire bond pad is within an outer edge of a top surface of the first wire bond pad; and
a boundary of an interface between the second supplemental conductor and the second wire bond pad is within an outer edge of a top surface of the second wire bond pad.

3. The device of claim 1, wherein:
the first supplemental conductor and the second supplemental conductor each comprise an electrically conductive material;
the supplemental conduit between the first wire and the first wire bond pad is a supplemental electrical conduit; and
the supplemental conduit between the second wire and the second wire bond pad is a supplemental electrical conduit.

4. The device of claim 3, wherein the first supplemental conductor and the second supplemental conductor each comprise a metal.

5. The device of claim 3, wherein the first supplemental conductor and the second supplemental conductor each comprise a conductive epoxy.

6. The device of claim 1 further comprising:
a third wire bond pad disposed on the first surface;
a third wire that is wire bonded to the third wire bond pad to form a contact between the third wire and the third wire bond pad; and
a third supplemental conductor disposed to form a supplemental conduit between the third wire and the third wire bond pad, wherein the third supplemental conductor is discrete from the first and second supplemental conductors.

7. The device of claim 1, wherein:
the first wire bond pad and the second wire bond pad are each an aluminum wire bond pad; and
the first wire and the second wire are each an aluminum bond wire.

8. The device of claim 1, wherein the device is a power diode.

9. A device comprising:
a wire bond between a wire and a site, the wire bond including an interface at which the wire and the site contact, the contact between the wire and the site characteristic of having been formed by a wire bonding process; and
a supplemental electrical conductor disposed over at least part of the wire bond to form an interface with the wire and an interface with the site, the supplemental electrical conductor providing a supplemental conduit for flow of electricity from the wire to the site.

10. The device of claim 9, wherein the supplemental electrical conductor comprises a metallic conductor.

11. The device of claim 9, wherein the supplemental electrical conductor comprises a solder.

12. The device of claim 9, wherein a boundary of an interface between the supplemental electrical conductor and the site is within an outer edge of a top surface of the site.

13. The device of claim 9, wherein a boundary of an interface between the supplemental electrical conductor and the site is at an outer edge of a top surface of the site.

14. The device of claim 9, wherein:
the device further comprises another wire bond between another wire and the site, the other wire bond including an interface at which the other wire and the site contact, the contact between the other wire and the site characteristic of having been formed by a wire bonding process; and
the supplemental electrical conductor is disposed over at least part of the other wire bond to form an interface with the other wire, the supplemental electrical conductor providing a supplemental conduit for flow of electricity from the other wire to the site.

15. The device according to claim 9, wherein:
the site is disposed on a surface of a component;
the device further comprises
another wire bond between another wire and another site, the other site being disposed on the surface of the component, the other wire bond including an interface at which the other wire and the other site contact, the contact between the other wire and the other site characteristic of having been formed by a wire bonding process, and
another supplemental electrical conductor disposed over at least part of the other wire bond to form an interface with the other wire and an interface with the other site, the other supplemental electrical conductor providing a supplemental conduit for flow of electricity from the other wire to the other site; and
the supplemental electrical conductor is discrete from the other supplemental electrical conductor.

16. The device of claim 15, wherein:
the device is a battery charger or a power converter for an LED device; and
the site and the other site are each respectively electrically coupled to one of an anode, a cathode, a source, a drain, a collector, or an emitter of the device.

17. The device according to claim 9, wherein:
the site is an aluminum bond pad; and
the wire is an aluminum bond wire.

18. A power component comprising:
a current flow path between electrical contact sites, wherein the current flow path includes a PN junction;
a wire bond pad disposed on a surface of a semiconductor die in which the power component is formed;
a wire that is wire bonded to the wire bond pad to form a contact between the wire and the wire bond pad; and
a supplemental conductor disposed to form a supplemental conduit between the wire and the wire bond pad, wherein a boundary of an interface between the supplemental conductor and the wire bond pad is within an outer edge of a top surface of the wire bond pad.

19. The power component of claim 18, wherein:
the power component further comprises another wire that is wire bonded to the wire bond pad to form a contact between the other wire and the wire bond pad; and
the supplemental conductor is disposed to form a supplemental conduit between the other wire and the wire bond pad.

20. The power component of claim 18, further comprising:
another wire bond pad disposed on the surface of the semiconductor die;
another wire that is wire bonded to the other wire bond pad to form a contact between the other wire and the other wire bond pad; and
another supplemental conductor disposed to form a supplemental conduit between the other wire and the other wire bond pad, wherein the supplemental conductor is discrete from the other supplemental conductor.

21. The power component of claim 18, wherein the supplemental conductor is disposed to form a supplemental electrical conduit between the wire and the wire bond pad.

22. The power component of claim 18, wherein the wire bonding of the wire to the wire bond pad has sufficient mechanical integrity to withstand handling during packaging of the semiconductor die in which the power component is formed.

23. The power component of claim 18, wherein the power component is a power diode.
